(19) United States
(12) Patent Application Publication
(10) Pub. No.: US 2019/0150317 A1
(43) Pub. Date: May 16, 2019

(54) DATA CENTER RACK MOUNTED LIQUID CONDUCTION COOLING APPARATUS AND METHOD

(71) Applicant: NAUTILUS DATA TECHNOLOGIES, INC., Pleasanton, CA (US)

(72) Inventors: Arnold Magcale, Danville, CA (US); Byron Taylor, San Jose, CA (US); Chase Abercrombie Ott, San Rafael, CA (US); James L. Connaughton, Palo Alto, CA (US)

(21) Appl. No.: 15/810,018

(22) Filed: Nov. 11, 2017

(51) Int. Cl. H05K 7/20

(52) U.S. Cl. CPC H05K 7/20263; H05K 7/20336; H05K 7/20272; H05K 7/20781

(57) ABSTRACT

Embodiments disclosed include a liquid-cooled cooling apparatus comprising a cooling structure comprising a first heat transfer element mounted to the electronics rack, and in operative communication with a thermally conductive material comprising at least one coolant-carrying channel extending there through in a closed loop. The liquid-cooled cooling apparatus further comprises a second heat transfer element coupled to the first heat transfer element and in operative communication with a thermally conductive material comprising at least one coolant-carrying channel extending there through in at least one of an open loop and a closed loop. The apparatus optionally includes a plurality of heat transfer elements, each heat transfer element being coupled to one or more heat-generating components of a respective electronic system of a plurality of electronic systems, and wherein each heat transfer element provides a thermal transport path from the one or more heat-generating components of the respective electronic system.

### FIELD

The present invention relates to heat transfer systems and methods, and more particularly, to liquid cooled conduction cooling apparatuses, liquid-cooled electronics racks and methods of fabrication thereof for removing heat generated by one or more electronic systems. Still more particulady, the present invention relates to cooling apparatuses and cooled electronics racks comprising a mounted, open and closed loop complimentary liquid-cooled cooling structure for the electronics rack.

### BACKGROUND OF THE INVENTION

A data center is a facility used to house computer systems and associated components. The computer systems, associated components housed in data centers and the environmental control cooling systems therein, consume significant amounts of energy. With the modern data center requiring several megawatts (MW) of power to support and cool the computer systems and associated components therein, resource utilization efficiency has become critical to evaluating data center performance.

To support the power consumption of the computer systems, associated components housed in the data centers and environmental control cooling systems, data centers consume a significant amount of water annually. Data center cooling system efficiency is critical to reduce the number of liters of water used per kilowatt hour (kWh) of energy consumed by the computer systems and associated components housed in the data center.

Prior art methods and systems have attempted to develop multi metric views to provide a broader understanding of data center performance. These multi metric views often take into account a single aspect of data center performance, Power Usage Effectiveness (PUE), a measure of how efficiently a data center uses energy. However, there still remains a need for a more nuanced and multi-dimensional metric that addresses the critical aspects of data center performance. In order to establish a more complete view of data center performance, there exists a requirement to assess key aspects of data center performance such as data center efficiency, data center availability and data center sustainability. There remains an additional need for a multi-dimensional metric that is easily scalable and that can accommodate additional new metrics in the future, as they are defined. Embodiments disclosed address precisely such a need.

With exponential increases in compute power density, data center electronics produce more and more heat. Failure to remove heat effectively results in increased device temperatures, potentially leading to thermal runaway conditions. The need for faster and more densely packed circuits has had a direct impact on the importance of thermal management. First, power dissipation, and therefore heat production, increases as device operating frequencies increase. Second, increased operating frequencies may be possible at lower device junction temperatures. Further, as more and more devices are packed onto a single chip, heat flux (Watts/cm²) increases, resulting in the need to remove more power from a given size chip or module. These trends have combined to create applications where it is no longer desirable to remove heat from modern devices solely by traditional air cooling methods, such as by using air cooled heat sinks with heat pipes or vapor chambers. Such air cooling techniques are inherently limited in their ability to extract heat from an electronic device with high power density.

The need to cool current and future high heat load, high heat flux electronic devices and systems therefore mandates the development of aggressive thermal management techniques using liquid cooling. Embodiments disclosed address precisely such a need.

### SUMMARY

One general aspect includes a liquid-cooled cooling structure including a first heat transfer element configured to mount to a housing within which the electronic system is contained, the liquid-cooled cooling structure including a thermally conductive material and including at least one coolant-carrying channel extending there through the housing. The liquid-cooled cooling structure also includes a second single or plurality of heat transfer elements coupled to one or more corresponding heat-generating components of the electronic system, and configured to physically connect with the coolant-carrying channel extending through the housing where each heat transfer element comprises a thermal transport path provided by the at least one coolant carrying channel from the one or more heat-generating components of the electronic system to the liquid-cooled cooling structure mounted to the housing. Preferably the first heat transfer element is operatively coupled to the at least one coolant carrying channel and the thermally conductive material further comprises a compartment for partial storage of coolant. The liquid-cooled cooling structure also includes a third heat transfer element operatively coupled to the first heat transfer element mounted to the housing, including a thermally conductive material.

One general aspect includes in an electronics rack, a liquid-cooled cooling apparatus including: a cooling structure including a first heat transfer element mounted to the electronics rack, and in operative communication with a thermally conductive material including at least one coolant-carrying channel extending there through in a closed loop; a second heat transfer element coupled to the first heat transfer element and in operative communication with a thermally conductive material including at least one coolant-carrying channel extending there through in at least one of an open loop and a closed loop; and a plurality of heat transfer elements, each heat transfer element being coupled to one or more heat-generating components of a respective electronic system of a plurality of electronic systems, and configured to physically contact the liquid-cooled cooling structure, where each heat transfer element physically engages the liquid-cooled cooling structure external the housing, and where each heat transfer element provides a thermal transport path from the one or more heat-generating components of the respective electronic system coupled thereto to the liquid-cooled cooling structure mounted to the housing.

An embodiment includes in an electronics rack housing, a liquid-cooled cooling apparatus comprising a cooling structure comprising a first heat transfer element mounted to the electronics rack housing, and in operative communication with a thermally conductive material comprising at least one first coolant-carrying channel extending there through the electronics rack, in a closed loop. The first heat transfer element further comprises at least one second coolant carrying channel operatively coupled to the first coolant carrying channel and further comprising an open loop coolant inlet plenum and coolant outlet plenum. According to an embodiment, a second plurality of heat transfer elements are coupled to a corresponding plurality of heat-generating components in an electronic system comprised in the electronics rack housing wherein each of the second plurality of heat transfer elements comprise a thermal transport path provided by the at least one first coolant carrying channel from each of the heat-generating components of the electronic system.

### BRIEF DESCRIPTION OF THE DRAWINGS

FIG. 1 is a first view of an electronics rack comprising a liquid-cooled cooling apparatus.

FIG. 2 is a second view of an electronics rack comprising a liquid-cooled cooling apparatus.

FIG. 3 is a third view of an electronics rack comprising a liquid-cooled cooling apparatus.

FIG. 4 is a fourth view of an electronics rack comprising a liquid-cooled cooling apparatus.

FIG. 5 is a fifth view of an electronics rack comprising a liquid-cooled cooling apparatus.

### DETAILED DESCRIPTION

The following is a detailed description of embodiments of the invention depicted in the accompanying drawings. The embodiments are introduced in such detail as to clearly communicate the invention. However, the embodiment(s) presented herein are merely illustrative, and are not intended to limit the anticipated variations of such embodiments; on the contrary, the intention is to cover all modifications, equivalents, and alternatives falling within the spirit and scope of the appended claims. The detailed descriptions below are designed to make such embodiments obvious to those of ordinary skill in the art.

As stated above, the traditional way of monitoring data center infrastructure, collecting data from infrastructure systems, and managing the systems to allow maximizing the operational efficiency is now struggling to cope with new challenges brought by the growing complexity of data centers. Traditional cooling systems and methods are hopelessly inadequate in light of current scale and increased compute density. Embodiments disclosed include systems and methods that address these challenges effectively and efficiently.

Embodiments disclosed include cooling apparatuses and systems for facilitating cooling of an electronic system, the cooling apparatus comprising a liquid-cooled cooling structure comprising a first heat transfer element configured to mount to a housing within which the electronic system is contained, the liquid-cooled cooling structure comprising a thermally conductive material and comprising at least one coolant-carrying channel extending there through. According to an embodiment the cooling apparatus may include a second single or plurality of heat transfer elements coupled to one or more corresponding heat-generating components of the electronic system, and configured to physically contact the liquid-cooled cooling structure when the liquid-cooled cooling structure is mounted to the housing, wherein each heat transfer element physically engages the liquid-cooled cooling structure, and wherein each heat transfer element provides a thermal transport path from the one or more heat-generating components of the electronic system to the liquid-cooled cooling structure mounted to the housing. An embodiment includes a third heat transfer element operatively coupled to the first heat transfer element mounted to the housing, comprising a thermally conductive material and at least one coolant carrying channel extending there through.

An embodiment includes a liquid-cooled cooling structure including a first heat transfer element configured to mount to a housing within which the electronic system is contained, the liquid-cooled cooling structure including a thermally conductive material and including at least one coolant-carrying channel extending there through the housing. The liquid-cooled cooling structure also includes a second single or plurality of heat transfer elements coupled to one or more corresponding heat-generating components of the electronic system, and configured to physically connect with the coolant-carrying channel extending through the housing where each heat transfer element comprises a thermal transport path provided by the at least one coolant carrying channel from the one or more heat-generating components of the electronic system to the liquid-cooled cooling structure mounted to the housing. Preferably the first heat transfer element is operatively coupled to the at least one coolant carrying channel and the thermally conductive material further comprises a compartment for partial storage of coolant.

According to an embodiment, the coolant carrying channel comprised in the cooling apparatus further comprises a single or plurality of configurable internal valves or gates operable to regulate the flow of the liquid according to a pre-defined temperature parameter. The valves or gates are mechanically, electronically or electro-mechanically controlled either by Data Center Infrastructure Management (DCIM) software, or autonomously. These dynamic flow control valves or gates to control temp cooling enables highly targeted, specific cooling at the subsystem level.

According to an embodiment of the cooling apparatus the heat transfer element comprises a heat transfer member configured to couple to the one or more heat-generating components of the electronic system and a thermal interface plate coupled to one end of the heat transfer member, the thermal transport path passing through the heat transfer member and the thermal interface plate.

In one embodiment of the cooling apparatus, the thermal interface plate is connected at a first end thereof to the heat transfer member and is configured to physically contact at a second end thereof to the liquid-cooled cooling structure when the liquid-cooled cooling structure is mounted to the housing, the heat transfer element is coupled to the one or more heat-generating components of the electronic system.

According to an embodiment of the cooling apparatus, at least one of the heat transfer member and the thermal interface plate comprises a heat pipe defining a portion of the thermal transport path and facilitating transport of heat generated by the one or more heat-generating components of the electronic system to the liquid-cooled cooling structure.

In a preferred embodiment, the liquid-cooled cooling structure is configured to cool multiple electronic systems via multiple respective heat transfer elements configured to couple thereto.

In an alternate embodiment of the cooling apparatus, the liquid-cooled cooling structure comprises multiple coolant-carrying channels extending there through, wherein the liquid-cooled cooling structure further comprises a coolant inlet plenum and a coolant outlet plenum in fluid communication with the multiple coolant-carrying channels. Preferably, the liquid-cooled cooling structure is a monolithic structure comprising the first heat transfer element configured to attach to the housing. The housing is an electronics rack comprising multiple electronic systems.

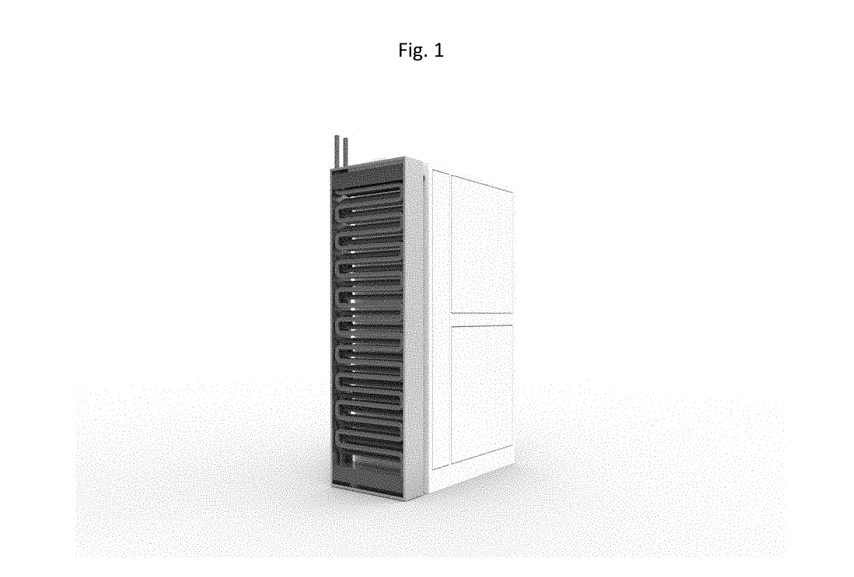

FIG. 1 is a first view of an electronics rack comprising a liquid-cooled cooling apparatus.

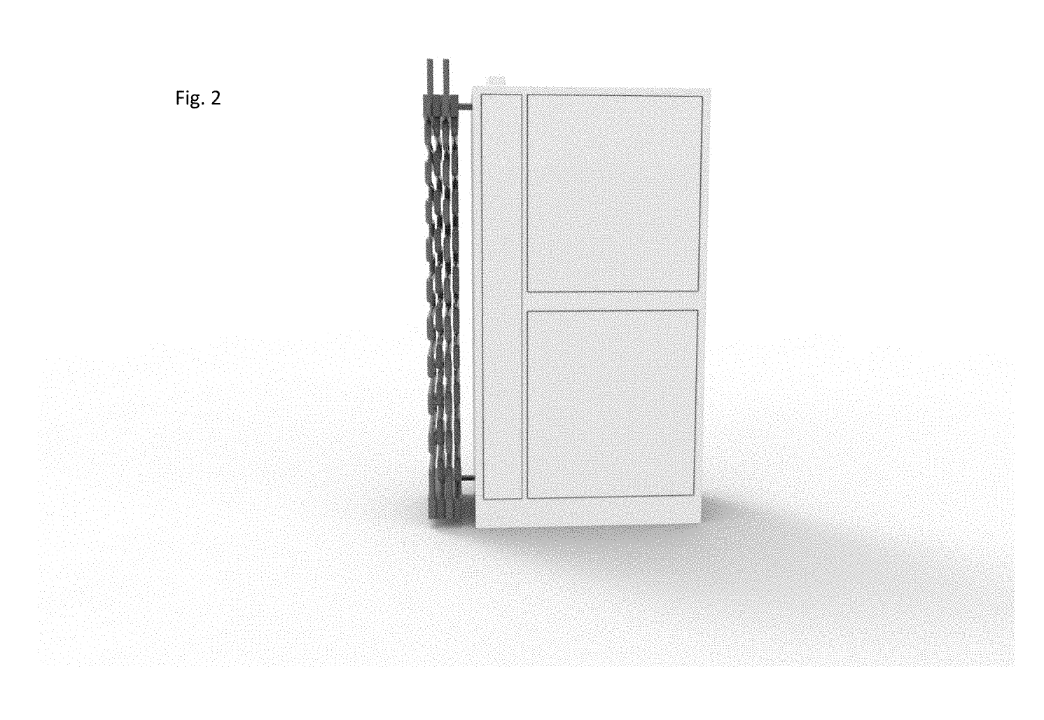

FIG. 2 is a second view of an electronics rack comprising a liquid-cooled cooling apparatus.

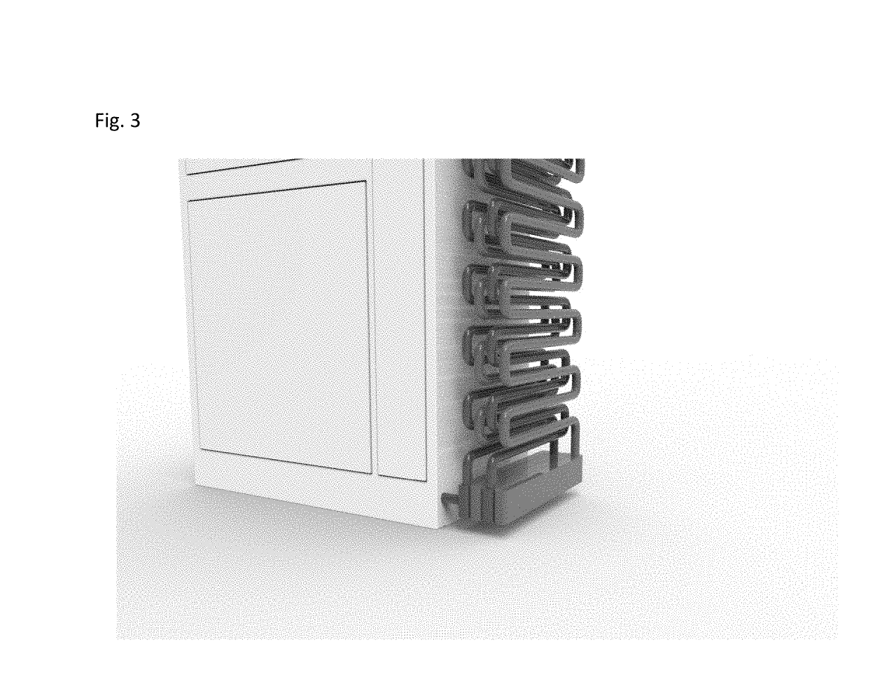

FIG. 3 is a third view of an electronics rack comprising a liquid-cooled cooling apparatus.

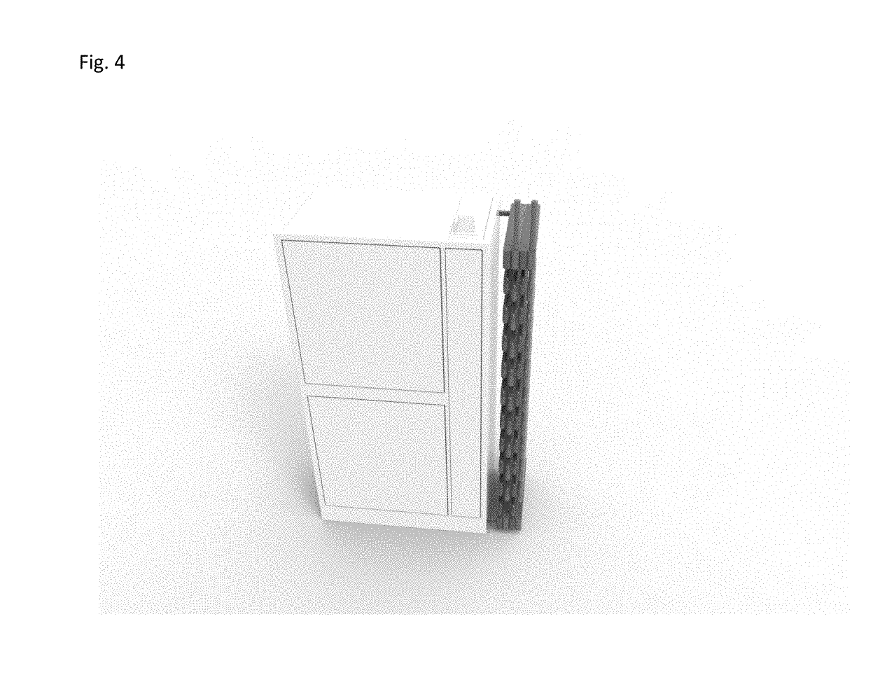

FIG. 4 is a fourth view of an electronics rack comprising a liquid-cooled cooling apparatus.

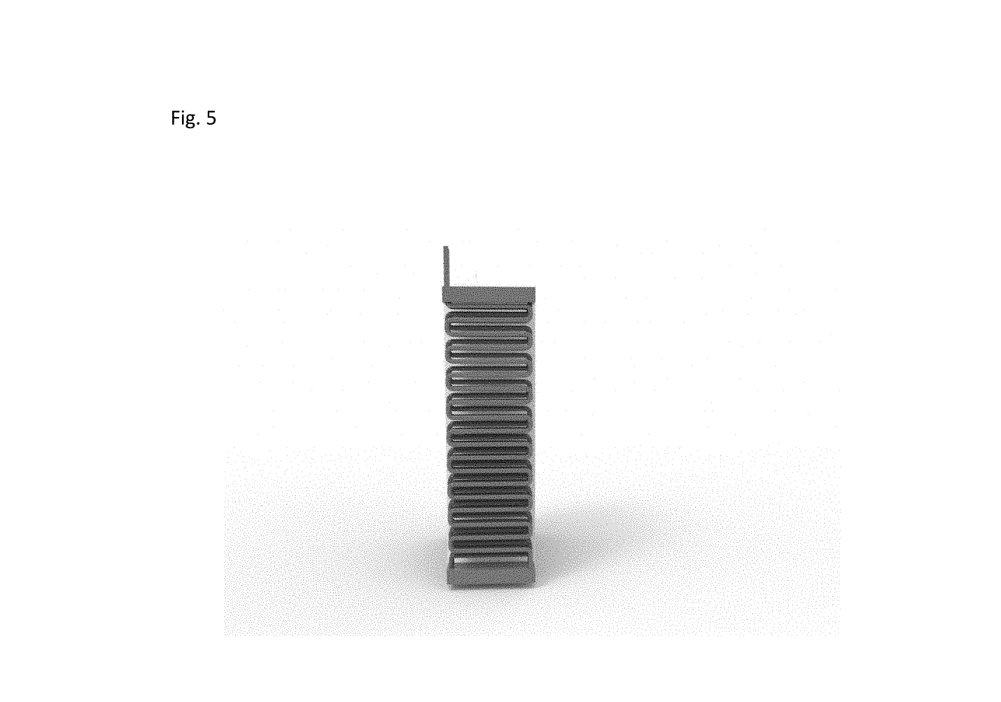

FIG. 5 is a fifth view of an electronics rack comprising a liquid-cooled cooling apparatus.

FIGS. 1-5 illustrate cooling apparatus (100, 200, 300, 400 and 500) for facilitating cooling of electronic system enclosed and mounted in housing (102, 202, 302, 402 and 502) the cooling apparatus comprising liquid-cooled cooling structure further comprising first heat transfer element (104, 204, 304, 404 and 504) configured to mount to housing within which the electronic system is contained, the liquid-cooled cooling structure comprising a thermally conductive material and comprising at least one coolant-carrying channel (106, 108, 206, 208, 306, 308, 406, 408 and 506, 508) extending there through housing (102, 202, 302, 402 and 502). The illustrated cooling apparatus further comprises a second single or plurality of heat transfer elements coupled to one or more corresponding heat-generating components of the electronic system, wherein each heat transfer element physically engages the liquid-cooled cooling structure, and wherein each heat transfer element provides a thermal transport path to and from the one or more heat-generating components of the electronic system to the liquid-cooled cooling structure mounted to the housing via coolant carrying channel (106, 108, 206, 208, 306, 308, 406, 408 and 506, 508). Preferably, coolant carrying channels (106, 108, 206, 208, 306, 308, 406, 408 and 506, 508) are operatively coupled to first heat transfer element (104, 204, 304, 404 and 504) mounted to the housing, comprising a thermally conductive material and at least one coolant carrying channel extending there through the housing.

According to an embodiment of the cooling apparatus, the electronic subsystem comprises multiple heat-generating components to be cooled, and wherein the second single or plurality of heat transfer elements are thermally interfaced to at least some heat-generating components of the multiple heat-generating components to be cooled, and are further configured to physically contact the liquid-cooled cooling structure when the liquid-cooled cooling structure is mounted to the housing.

Embodiments disclosed include, in an electronics rack, a liquid-cooled cooling apparatus comprising a cooling structure comprising a first heat transfer element mounted to the electronics rack, and in operative communication with a thermally conductive material comprising at least one coolant-carrying channel extending there through in a closed loop. The liquid cooling apparatus comprises a second heat transfer element coupled to the first heat transfer element and in operative communication with a thermally conductive material comprising at least one coolant-carrying channel extending there through in at least one of an open loop and a closed loop. According to an additional and alternate embodiment, the liquid cooling apparatus comprises a plurality of heat transfer elements, each heat transfer element being coupled to one or more heat-generating components of a respective electronic system of a plurality of electronic systems, and configured to physically contact the liquid-cooled cooling structure, wherein each heat transfer element physically engages the liquid-cooled cooling structure external the housing, and wherein each heat transfer element provides a thermal transport path from the one or more heat-generating components of the respective electronic system coupled thereto to the liquid-cooled cooling structure mounted to the housing.

According to an embodiment of the liquid-cooled electronics rack, the liquid-cooled cooling structure comprises at least one coolant-carrying channel extending there through, and wherein the liquid-cooled cooling structure further comprises a coolant inlet plenum (112, 212, 312, 412 and 512) and a coolant outlet plenum (114, 214, 314, 414 and 514) in fluid communication with the coolant-carrying channels, wherein the coolant inlet plenum and the coolant outlet plenum are plenums mounted to the electronics rack.

According to an embodiment of the liquid-cooled electronics rack, each heat transfer element comprises a heat transfer member coupled to the one or more heat-generating components of the respective electronic system and a thermal interface plate extending from the one end of the heat transfer member, wherein the respective thermal transport path passes through the heat transfer member and the thermal interface plate.

According to an embodiment of the liquid-cooled electronics rack, at least one of the heat transfer member and the thermal interface plate of at least one heat transfer element comprises a heat pipe defining a portion of the thermal transport path thereof and facilitating transport of heat generated by the one or more heat-generating components of the respective electronic system to the liquid-cooled cooling structure.

Preferably, in the liquid-cooled electronics rack the liquid-cooled cooling structure is configured to cool multiple electronic systems via multiple, respective heat transfer elements coupled thereto.

Embodiments disclosed include systems and methods for cooling data centers that contribute to optimizing data center performance and sustainability through efficient cooling and drastically reduced power consumption. Embodiments disclosed address the long standing need to cool current and future high heat load, high heat flux electronic devices and systems through improved management techniques using liquid cooling.

Embodiments disclosed enable drastic reduction in power consumption through smart management of cooling power, and leveraging of environmental conditions to optimize cooling power consumption. Systems and methods disclosed enable huge savings in data center power consumption. Predictive analytics software control enables real-time computing power consumption estimation and thereby optimization of computing and cooling power consumption.

Embodiments disclosed include systems and methods that leverage multi-metric views that provide real-time actionable intelligence on data center performance and cooling performance. These multi-metric views attempt to take into account aspects of performance by bringing together the Power Usage Effectives (PUE) ratio, IT Thermal Conformance and IT Thermal Resilience thereby enabling real-time optimization through correlation of computing, infrastructure and cooling performance. Embodiments disclosed further enable nuanced and multi-dimensional metric that addresses the most critical aspects of a data center's cooling performance. In order to establish a more complete view of facility cooling, the requirement to calculate cooling effectiveness and the data center's future thermal state is also critical. Embodiments disclosed enable easily scalable multi-dimensional metrics that can accommodate additional new metrics in the future, as they are defined.

Embodiments disclosed include improved, superior thermal conduction apparatus and methods for facilitating cooling of a rack based electronic system. According to a preferred embodiment, the thermal conduction apparatus is mounted to the back of the rack. Preferably, circulation liquid coolant includes incorporating negative pressure to negate any spills during leakage. According to an embodiment, the liquid-cooling apparatus incorporates secondary closed loop for direct cooling. In an additional embodiment heat exchangers comprising horizontal fins where the heated fluid from the servers pass-through which interlaces with opposing horizontal fins where the cold water passes through and this is where the heat conduction occurs (at the back of the rack). Preferably, there are no “removable components” each rack will have its own apparatus. According to one embodiment of the apparatus, there is no requirement for any air flow.

Since various possible embodiments might be made of the above invention, and since various changes might be made in the embodiments above set forth, it is to be understood that all matter herein described or shown in the accompanying drawings is to be interpreted as illustrative and not to be considered in a limiting sense. Thus it will be understood by those skilled in the art of systems and methods that facilitate cooling of electronic systems, and more specifically automated cooling infrastructure especially pertaining to data centers, that although the preferred and alternate embodiments have been shown and described in accordance with the Patent Statutes, the invention is not limited thereto or thereby.

The figures illustrate the architecture, functionality, and operation of possible implementations of systems, methods and computer program products according to various embodiments of the present invention. It should also be noted that, in some alternative implementations, the functions noted/illustrated may occur out of the order noted in the figures. For example, two blocks shown in succession may, in fact, be executed concurrently, or the blocks may sometimes be executed in the reverse order, depending upon the functionality involved.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In general, the routines executed to implement the embodiments of the invention, may be part of an operating system or a specific application, component, program, module, object, or sequence of instructions. The computer program of the present invention typically is comprised of a multitude of instructions that will be translated by the native computer into a machine-accessible format and hence executable instructions. Also, programs are comprised of variables and data structures that either reside locally to the program or are found in memory or on storage devices. In addition, various programs described hereinafter may be identified based upon the application for which they are implemented in a specific embodiment of the invention. However, it should be appreciated that any particular program nomenclature that follows is used merely for convenience, and thus the invention should not be limited to use solely in any specific application identified and/or implied by such nomenclature.

The present invention and some of its advantages have been described in detail for some embodiments. It should be understood that although the system and process is described with reference to liquid-cooled conduction cooling structures in data centers, the system and method is highly reconfigurable, and may be used in other contexts as well. It should also be understood that various changes, substitutions and alterations can be made herein without departing from the spirit and scope of the invention as defined by the appended claims. An embodiment of the invention may achieve multiple objectives, but not every embodiment falling within the scope of the attached claims will achieve every objective. Moreover, the scope of the present application is not intended to be limited to the particular embodiments of the process, machine, manufacture, composition of matter, means, methods and steps described in the specification. A person having ordinary skill in the art will readily appreciate from the disclosure of the present invention that processes, machines, manufacture, compositions of matter, means, methods, or steps, presently existing or later to be developed are equivalent to, and fall within the scope of, what is claimed. Accordingly, the appended claims are intended to include within their scope such processes, machines, manufacture, compositions of matter, means, methods, or steps.

We claim:

1. A cooling apparatus for facilitating cooling of an electronic system, the cooling apparatus comprising:
a liquid-cooled cooling structure comprising a first heat transfer element configured to mount to a housing within which the electronic system is contained, the liquid-cooled cooling structure comprising a thermally conductive material and comprising at least one coolant-carrying channel extending there through the housing;
a second single or plurality of heat transfer elements coupled to one or more corresponding heat-generating components of the electronic system, and configured to physically contact the liquid-cooled cooling structure, wherein each heat transfer element comprises a thermal transport path provided by the at least one coolant carrying channel from the one or more heat-generating components of the electronic system to the liquid-cooled cooling structure mounted to the housing; and
wherein the first heat transfer element is operatively coupled to the at least one coolant carrying channel and the thermally conductive material further comprises a compartment for partial storage of coolant.

2. The cooling apparatus of claim 1, wherein the second heat transfer element comprises a heat transfer member configured to couple to the one or more heat-generating components of the electronic system and a thermal interface plate coupled to one end of the heat transfer member, the thermal transport path passing through the heat transfer member and the thermal interface plate.

3. The cooling apparatus of claim 2, wherein the thermal interface plate is connected at a first end thereof to the heat transfer member and is configured to physically contact at a second end thereof to the liquid-cooled cooling structure via the at least one coolant carrying channel.

4. The cooling apparatus of claim 3, wherein at least one of the heat transfer member and the thermal interface plate comprises a heat pipe defining a portion of the thermal transport path and facilitating transport of heat generated by the one or more heat-generating components of the electronic system to the liquid-cooled cooling structure via the at least one coolant-carrying channel.

5. The cooling apparatus of claim 1, further comprising a plurality of second heat transfer elements coupled to a corresponding plurality of heat-generating components of the electronic system, and configured to physically contact the liquid-cooled cooling structure wherein each of the plurality of second heat transfer elements comprise a thermal transport path provided by the at least one coolant carrying channel from the plurality of heat-generating components of the electronic system to the liquid-cooled cooling structure mounted to the housing.

6. The cooling apparatus of claim 1, wherein the liquid-cooled cooling structure comprises a plurality of coolant-carrying channels extending there through the housing, and wherein the liquid-cooled cooling structure further comprises a coolant inlet plenum and a coolant outlet plenum in fluid communication with the multiple coolant-carrying channels, the liquid-cooled cooling structure being a monolithic structure comprising the first heat transfer element configured to attach to the housing.

7. The cooling apparatus of claim 1, wherein the electronic subsystem comprises multiple heat-generating components to be cooled, and wherein the second single or plurality of heat transfer elements are thermally interfaced to at least some heat-generating components of the multiple heat-generating components to be cooled, and are further configured to physically contact the liquid-cooled cooling structure when the liquid-cooled cooling structure is mounted to the housing.

8. In an electronics rack housing, a liquid-cooled cooling apparatus comprising:
a cooling structure comprising a first heat transfer element mounted to the electronics rack housing, and in operative communication with a thermally conductive material comprising at least one first coolant-carrying channel extending there through the electronics rack, in a closed loop;
wherein the first heat transfer element further comprises at least one second coolant carrying channel operatively coupled to the first coolant carrying channel and further comprising an open loop coolant inlet plenum and coolant outlet plenum; and
a second plurality of heat transfer elements coupled to a corresponding plurality of heat-generating components in an electronic system comprised in the electronics rack housing wherein each of the second plurality of heat transfer elements comprises a thermal transport path provided by the at least one first coolant carrying channel from each of the heat-generating components of the electronic system.

9. The liquid-cooled electronics rack of claim 8, wherein the coolant inlet plenum and the coolant outlet plenum are mounted to the electronics rack.

10. The liquid-cooled electronics rack of claim 8, wherein each of the second plurality of heat transfer elements comprises a heat transfer member coupled to the one or more heat-generating components of the electronic system and a thermal interface plate having a first end coupled to the heat transfer member, and a second end coupled to the liquid-cooled cooling structure via the at least one coolant carrying channel.

11. The liquid-cooled electronics rack of claim 10, wherein the thermal interface plate is further coupled to a heat pipe comprised in the at least one first coolant-carrying channel defining a portion of the thermal transport path thereof and facilitating transport of heat generated by the one or more heat-generating components of the respective electronic system to the liquid-cooled cooling structure.

12. The liquid-cooled electronics rack of claim 10, wherein the liquid-cooled cooling structure is configured to cool multiple electronic systems via multiple, respective heat transfer elements coupled thereto.
